(19) United States
(12) Patent Application Publication
(10) Pub. No.: US 2016/0262254 A1
(43) Pub. Date: Sep. 8, 2016

(54) INTRINSICALLY SAFE RADIO FREQUENCY (RF) ADAPTER

(71) Applicant: Honeywell International Inc., Morristown, NJ (US)

(72) Inventor: BART MEIJER, ZUID HOLLAND (NL)

(21) Appl. No.: 14/638,795

(22) Filed: Mar. 4, 2015

(51) Int. Cl. H05K 1/02; H01R 24/40; G01F 23/284

(52) U.S. Cl. CPC H05K 1/025; G01F 23/284; H01R 24/40

(57) ABSTRACT

An intrinsic safety (IS) radio frequency (RF) adapter combination includes a multi-layer printed circuit board (PCB) including a dielectric substrate material having a 25° C. loss tangent of <0.010 at 10 GHz having a first layer on a first side and a second layer on a second side. The first layer includes an IS circuit including a signal trace having at least one series capacitor that has a 25° C. capacitance less than or equal to (≦) 50 pico Farads (pF) coupled between a core of a tank-side coaxial connector and a core of a radar level gauge (RLG)-side coaxial connector, wherein a shield of the RLG-side coaxial connector is coupled to a first ground plane. The second layer includes a second ground plane coupled to a shield of the tank-side coaxial connector. The first ground plane at least partially overlaps the second ground plane.

### FIELD

Disclosed embodiments relate to intrinsic safety circuits and devices, including for radar level gauging.

### BACKGROUND

In industrial process control systems, wireless networks are widely deployed to support sensing and monitoring of industrial processes. Such networks permit industrial processes to be monitored utilizing a wireless sensor without incurring the setup costs typically associated with wired devices. Such wireless sensors, however, are often required to be compliant with intrinsic safety (IS) standards.

Zone 0 (e.g., highly hazardous) can comprise the inside of a storage or processing tank containing an explosive gas or liquid, so that when level measurements are made by an antenna, probe or waveguide inside the tank that is connected to a radar level gauge (RLG) above the tank the RLG is generally zone 1. Accordingly, it is generally needed for the RLG system to be designed for the hazardous location.

RLGs include a transceiver along with other electronics (e.g., processor, memory) on an RLG board often connected to an external antenna that permits communications remote locations, such as to a process controller and to a control room of a plant. For the RLG system to be IS, a common constraint is that the tank antenna's ground and the RLG board's ground are to be completely isolated by certain distances. Unfortunately, this type of arrangement disturbs the matching between the tank antenna and the RLG board, and can cause high RF or other losses due to ground discontinuities.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed embodiments include intrinsic safety (IS) radio frequency (RF) adapter combinations for RF radar wave transmitting and receiving that include a multi-layer printed circuit board (PCB) including a dielectric substrate material having a 25° C. loss tangent of <0.010 at 10 GHz having a first layer on a first side and a second layer on a second side. The first layer includes an IS circuit including a signal trace having at least one series capacitor that has a 25° C. capacitance less than or equal to (≦) 50 Pico Farads (pF) coupled between a core of a tank-side coaxial connector and a core of a radar level gauge (RLG)-side coaxial connector, wherein a shield of the RLG-side coaxial connector is coupled to a first ground plane. As used herein, the term “coaxial connector” includes variants including SubMiniature version C (SMC) connectors, and SubMiniature version B (SMB) connectors.

The second layer includes a second ground plane coupled to a shield of the tank-side coaxial connector. The first ground plane at least partially overlaps the second ground plane. Series capacitor(s) are recognized to meet the IS requirement without the need for other components and therefore reduce the mechanical components used for the connection of the RLG measurement instrument to the tank as compared to known IS RF adapter combinations.

Disclosed IS RF adapter combinations enable radar-based level sensing systems to have a RLG directly coupled by a direct coupling connection to an antenna, waveguide or probe in the tank (tank antenna). As used herein a “direct coupling connection” is a signal connection that removes standing waves throughout the full signal propagation path, in contrast to a signal connection having standing waves generated resulting from conventional electromagnetic wave propagation through a dielectric material.

### BRIEF DESCRIPTION OF THE DRAWINGS

FIG. 1A is a block diagram depiction of an example IS RF adapter combination positioned between a RLG having an optional antenna and a tank antenna adapted for positioning within a tank for transmitting radar signals into the tank and receiving reflected echo signals, according to an example embodiment.

FIG. 1B a scanned perspective top-side image of an example IS RF adapter combination, according to an example embodiment.

FIG. 2 depicts a radar-based level sensing system comprising an RLG coupled to an example IS RF adapter both in a metal enclosure mounted over a nozzle of a tank having hazardous material therein, where the IS RF adapter enables a direct coaxial coupling between the RLG and the tank antenna, according to an example embodiment.

### DETAILED DESCRIPTION

Disclosed embodiments are described with reference to the attached figures, wherein like reference numerals are used throughout the figures to designate similar or equivalent elements. The figures are not drawn to scale and they are provided merely to illustrate certain disclosed aspects. Several disclosed aspects are described below with reference to example applications for illustration. It should be understood that numerous specific details, relationships, and methods are set forth to provide a full understanding of the disclosed embodiments.

One having ordinary skill in the relevant art, however, will readily recognize that the subject matter disclosed herein can be practiced without one or more of the specific details or with other methods. In other instances, well-known structures or operations are not shown in detail to avoid obscuring certain aspects. This Disclosure is not limited by the illustrated ordering of acts or events, as some acts may occur in different orders and/or concurrently with other acts or events. Furthermore, not all illustrated acts or events are required to implement a methodology in accordance with the embodiments disclosed herein.

Also, the terms “coupled to” or “couples with” (and the like) as used herein without further qualification are intended to describe either an indirect or direct electrical connection. Thus, if a first device “couples” to a second device, that connection can be through a direct electrical connection where there are only parasitics in the pathway, or through an indirect electrical connection via intervening items including other devices and connections. For indirect coupling, the intervening item generally does not modify the information of a signal but may adjust its current level, voltage level, and/or power level.

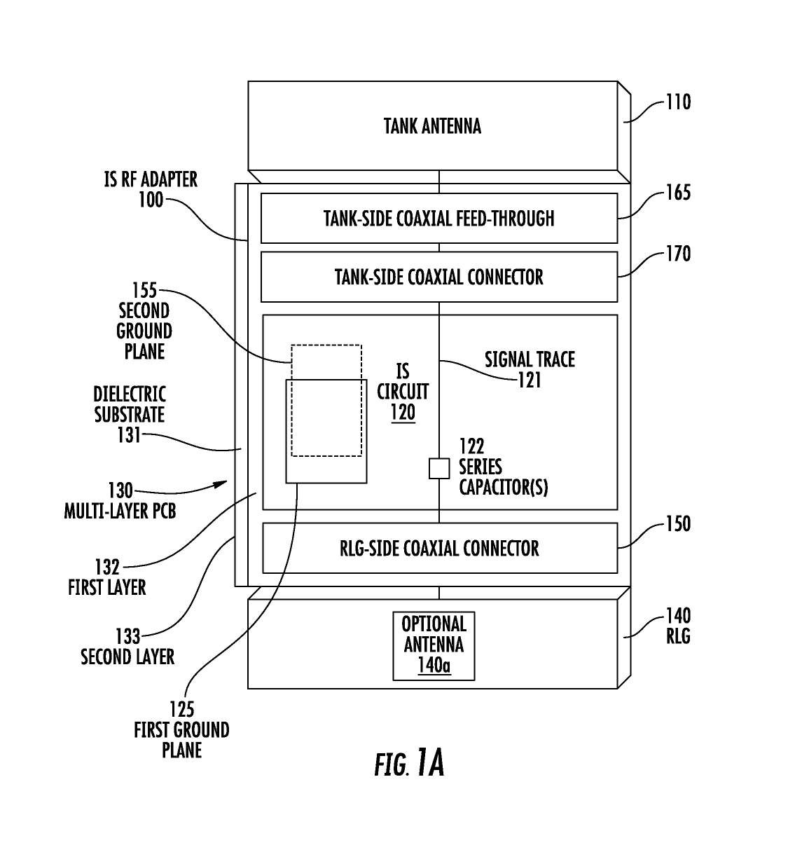

FIG. 1A is a block diagram depiction of an example IS RF in-line adapter combination 100 positioned between a RLG 140 having an optional antenna 140a and a tank antenna 110 that is adapted for positioning within a tank for transmitting radar signals into the tank and receiving reflected echo signals, according to an example embodiment. The tank antenna 110 is through which the RF radar signal typically at a frequency of at least several GHz (e.g., ≧5 GHz) is sent to and the reflected signal responsive to this signal (echo signal) is received by the tank antenna 110. Calculating the liquid (or other product material such as a powder) level based on analyzing reflected echo signals is the core function of the RLG 140.

IS RF adapter combination 100 includes a multi-layer PCB 130 comprising a dielectric substrate material 131 having a 25° C. loss tangent of <0.010 at 10 GHz including a first layer 132 on a first side (shown as a top side) and a second layer 133 on a second side shown as a bottom side opposite the first side. Although shown and described herein as having 2 layers, PCB 130 may have 3 or more layers. The first layer 132 provides an IS circuit 120 including a signal trace 121 having at least one series capacitor 122 (thus being in the signal path) that has a 25° C. capacitance less than or equal to (≦) 50 Pico Farads (pF) coupled between a core of a tank-side coaxial connector 170 and a core of a RLG-side coaxial connector 150, wherein a shield of the RLG-side coaxial connector 150 is coupled to a first ground plane 125 that is used by the RLG 140.

The second layer 133 includes a second ground plane 155 coupled to a shield of the tank-side coaxial connector 170 which provides a ground for the tank antenna 110. The first ground plane 125 is shown at least partially overlapping the second ground plane 155. The spatial extent of the ground planes shown and their degree of overlap shown in FIG. 1 is arbitrary. There is no direct (DC) ground coupling between the first ground plane 125 and second ground plane 155 and thus no direct connection between the tank antenna 110 and the circuitry of the RLG 140 at DC and at relatively low frequencies (e.g., <100 MHz).

As noted above, dielectric substrate material 131 of the PCB 130 comprises a dielectric material having a 25° C. loss tangent of <0.010 at 10 GHz, which is typically <0.005 at 10 GHz. Thus, conventional epoxy-based PCB materials such as FR4 (a composite material composed of woven fiberglass cloth with an epoxy resin binder) are not used. Instead of a board material such as Polytetrafluoroethylene (Teflon or PTFE) having a low loss tangent (tan 6) or dissipation factor of 0.00032 at 10 GHz is generally used. RO4360 substrates being low loss, glass-reinforced, hydrocarbon ceramic-filled thermoset materials have a reported loss tangent (tan) δ of 0.003 when tested at 2.5 GHz which can also be used. Also, RF-35A comprising an organic-ceramic laminate having woven glass reinforcement can also generally be used which has a reported loss tan of 0.0032 at 10 GHz.

Disclosed embodiments recognize series capacitor(s) alone can provide the IS function of limiting power delivered to the tank antenna 110 to prevent explosions without requiring a shunt connection to ground. The safety standards allow this arrangement as an effective method to block all DC current along the signal path to the tank antenna 110 and due to the value of the capacitor(s) being fairly low, on the order of magnitude 10 pF, the energy let-through for AC current by the capacitor(s) is also restricted to levels that the safety standards allow.

For example, for a capacitor having a 10 pF capacitance at 10 GHz the capacitive impedance (Xc) of the capacitor is about 6 ohms so that an RF signal can be transmitted in either direction with low power loss. Accordingly, there is no need for at least 1 zener diode or similar device from the signal trace 121 to ground (e.g., first ground plane 125) for limiting power because safety standards (e.g., IEC 60079-11) generally consider 250 Vac to be worst-case voltage present during fault conditions and as noted above a capacitance value of about 10 pF is sufficient to limit the energy reaching the tank antenna 110. For example, industry standard ceramic chip capacitors can be used as the series capacitor(s) 122. However, disclosed IS circuits 120 can optionally include one or more zener diode(s) or similar device(s) coupled between the signal trace 121 and ground.

Regarding the relationship and interaction between the first ground plane 125 and second ground plane 155 one may consider a conventional coaxial signal cable that has a center core conductor (typically metal) as well as an outer typically metal shield to establish a loop for the signal to travel. One path propagates along the signal trace 121 through the series capacitor(s) 122 and the return path (like an outer metal shield of a coaxial cable) is passed on via the first ground plane 125 which then propagates through the dielectric substrate 131 of the PCB 130 (dielectric substrate 131 provides low impedance at 10 GHz, for example, 10 ohms) onto the second ground plane 155 which partially overlaps the first ground plane 125.

FIG. 1B a scanned perspective top-side image of an example IS RF adapter combination 100′. Series capacitors are shown as 122a, 122b and 122c. Mounting studs are shown as 181. Coaxial connectors are shown as RLG-side coaxial connector 150 and tank-side coaxial connector 170. The first layer 132 of the PCB is shown as being a top side layer.

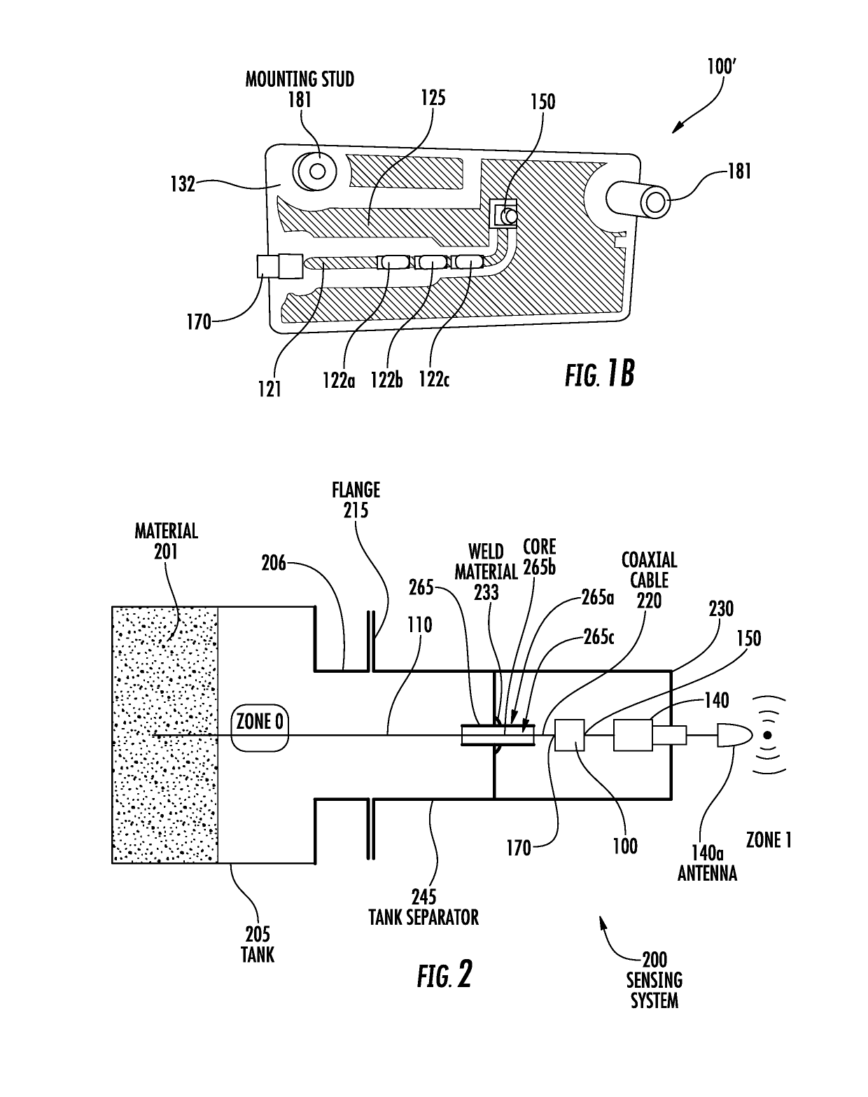

FIG. 2 depicts a radar-based level sensing system (sensing system) 200 coupled to a top of a tank 205, according to an example embodiment. Sensing system 200 comprises an RLG 140 coupled to an example IS RF adapter 100 both in a metal enclosure 230 mounted to a tank separator 245 over a nozzle 206 of a tank 205 having hazardous material 201 therein, where the IS RF adapter 100 is coaxially coupled to a tank antenna 110 in the tank 205.

Although shown as being a contact radar system, such as a guided wave radar (GWR) system that utilizes time domain reflectometry (TDR), radar-based level sensing system 200 may also be configured as a non-contact radar system. Sensing system 200 may be configured as a continuous wave radar system that is Doppler-based, or a pulse radar system. The radar signal used may be at a frequency between 5 GHz and 100 GHz. RLG 140 is shown having an optional antenna 140a, or instead may have a wired connection for wired communications instead. The hazardous material 201 in the tank 205 renders the full inside of the tank 205 zone 0 as shown so that the tank antenna 110 resides in zone 0 being inside the storage tank 205. The IS RF adapter 100 is generally a complete mechanical unit which meets government standards including European standards such as Appareils destinés à être utilisés en ATmosphères Explosives (ATEX) & international electrotechnical commission (IECEx) certification requirements.

A flange 215 is shown on the top of the nozzle 206 that optional tank separator 245 is on. There is also a coaxial cable 220 having a first end coupled to the tank-side coaxial connector 170 and a second end opposite the first end. A coaxial feed-through 265 is coupled to the second end of the coaxial cable 220. Coaxial feed-through 265 typically >10 mm in length includes a metallic sleeve 265a with a wall thickness typically >1 mm comprising a corrosion resistant material such as stainless steel and a core 265b separated a bushing insulator 265c (e.g., melted glass, brazed ceramics). A metal flameproof enclosure (metal enclosure) 230 includes a tank-side aperture, wherein the coaxial feed-through 265 is partially within the metal enclosure 230 and the RF adapter combination 100.

Only electrically conductive parts of the tank antenna 110 and the shield of the tank-side coaxial feed-through 165 and tank-side coaxial connector 170 are generally needed to be electrically isolated from both the metal enclosure 230 for the RLG 140 as well as from the tank 205 when the tank is a metal or metal alloy tank, as well as from the electronics of the RLG 140 by a dielectric material coating material to meet an electrical isolation requirement. IS RF adapter 100, RLG 140, tank-side coaxial connector 170 are sealed within the metal enclosure 230. The coaxial feed-through 265 includes an outer corrosion resistant metal sleeve (shield) 265a and an inner core 265b, further comprising a weld material 233 welding the coaxial feed-through 265 to a metal of the metal enclosure 230.

The metal for the metal enclosure 230 can be generally from any suitable metallic material that offers sufficient strength. Examples of such materials include stainless steel, aluminum, etc. Metal enclosure 230 is generally a flameproof and explosion proof enclosure, with internal potting to meet flameproof (explosion proof) requirements and IS requirements.

A significant benefit recognized herein is that disclosed IS RF adapters 100 provide essentially a direct connection of the RF signal which is a significantly better communication path and a more reliable method of RF signal propagation as opposed to conventional IS RF adapters which rely on a signal path including electromagnetic wave propagation through a dielectric material which involves standing waves. Disclosed arrangements instead provide a direct connection from the tank antenna to the RLG without any specific RF standing wave through dielectric feed-through assembly.

While various disclosed embodiments have been described above, it should be understood that they have been presented by way of example only, and not limitation. Numerous changes to the subject matter disclosed herein can be made in accordance with this Disclosure without departing from the spirit or scope of this Disclosure. In addition, while a particular feature may have been disclosed with respect to only one of several implementations, such feature may be combined with one or more other features of the other implementations as may be desired and advantageous for any given or particular application.

1. An intrinsic safety (IS) radio frequency (RF) adapter combination, comprising:
a multi-layer printed circuit board (PCB) comprising a dielectric substrate material having a 25° C. loss tangent of <0.010 at 10 GHz including a first layer on a first side and a second layer on a second side;
said first layer including an IS circuit including a signal trace having at least one series capacitor that has a 25° C. capacitance less than or equal to (≦) 50 Pico Farads (pF) coupled between a core of a tank-side coaxial connector and a core of a radar level gauge (RLG)-side coaxial connector, wherein a shield of said RLG-side coaxial connector is coupled to a first ground plane;
said second layer including a second ground plane coupled to a shield of said tank-side coaxial connector, and
wherein said first ground plane at least partially overlaps said second ground plane.

2. The IS RF adapter combination of claim 1, further comprising:
a coaxial cable having a first end coupled to said tank-side coaxial connector and a second end opposite said first end;
a coaxial feed-through coupled to said coaxial cable, and
a metal enclosure having including a tank-side aperture, wherein said coaxial feed-through is partially within said metal enclosure and wherein IS RF adapter combination and said coaxial cable are both sealed within said metal enclosure.

3. The IS RF adapter combination of claim 2, wherein said coaxial feed-through includes an outer corrosion resistant metal sleeve, further comprising a weld material welding said coaxial feed-through to a metal of said metal enclosure.

4. The IS RF adapter combination of claim 3, further comprising a RLG within said metal enclosure coupled to said RLG-side coaxial connector.

5. The IS RF adapter combination of claim 1, wherein said at least one series capacitor includes a first series capacitor and at least a second series capacitor.

6. The IS RF adaptor combination of claim 5, wherein said IS circuit consists of said first series capacitor and said second series capacitor.

7. The IS RF adapter combination of claim 1, wherein said 25° C. capacitance of said series capacitor is ≦10 pF.

8. The IS RF adaptor combination of claim 1, wherein said dielectric substrate material has a 25° C. loss tangent of <0.005 at 10 GHz.

9. A radar-based level sensing system (sensing system), comprising:
a radar level gauge (RLG);
a tank antenna within a tank coupled to said RLG by an intrinsic safety (IS) radio frequency (RF) adapter combination, said IS RF adapter combination including:
a multi-layer printed circuit board (PCB) comprising a dielectric substrate material having a 25° C. loss tangent of <0.010 at 10 GHz including a first layer on a first side and a second layer on a second side;
said first layer including an IS circuit including a signal trace having at least one series capacitor that has a 25° C. capacitance less than or equal to (≦) 50 Pico Farads (pF) coupled between a core of a tank-side coaxial connector and a core of a RLG-side coaxial connector, wherein a shield of said RLG-side coaxial connector is coupled to a first ground plane;
said second layer including a second ground plane coupled to a shield of said tank-side coaxial connector, and
wherein said first ground plane at least partially overlaps said second ground plane;
a coaxial cable having a first end coupled to said tank-side coaxial connector and a second end opposite said first end;
a coaxial feed-through coupled to said coaxial cable, and
a metal enclosure having including a tank-side aperture, wherein said coaxial feed-through is partially within said metal enclosure, and wherein said RLG, said IS RF adapter combination and said coaxial cable are all sealed within said metal enclosure.

10. The sensing system of claim 9, wherein said coaxial feed-through includes an outer corrosion resistant metal sleeve, further comprising a weld material welding said coaxial feed-through to a metal of said metal enclosure.

11. The sensing system of claim 9, wherein said at least one series capacitor includes a first series capacitor and at least a second series capacitor.

12. A method of level sensing, comprising:
providing a radar-based level sensing system (sensing system) including a radar level gauge (RLG) directly coupled by a direct coupling connection to a tank antenna within a tank having a material therein by an intrinsic safety (IS) radio frequency (RF) adapter combination,
transmitting a radar signal generated by said RLG over said direct coupling connection to said tank antenna;
responsive to said radar signal interacting with said material, receiving a reflected echo signal over said direct coupling connection at said RLG, and
determining a level of said material in said tank from said echo signal.

13. The method of claim 12, wherein said IS RF adapter combination comprises:
a multi-layer printed circuit board (PCB) comprising a dielectric substrate material having a 25° C. loss tangent of <0.010 at 10 GHz including a first layer on a first side and a second layer on a second side;
said first layer including said IS circuit including a signal trace having at least one series capacitor that has a 25° C. capacitance less than or equal to (≦) 50 Pico Farads (pF) coupled between a core of a tank-side coaxial connector and a core of a RLG-side coaxial connector, wherein a shield of said RLG-side coaxial connector is coupled to a first ground plane;
said second layer including a second ground plane coupled to a shield of said tank-side coaxial connector, and
wherein said first ground plane at least partially overlaps said second ground plane.

14. The method of claim 12, wherein said radar signal is at a frequency between 5 GHz and 100 GHz.

15. The method of claim 12, wherein said method comprises contact radar-based level sensing.
